(19) United States
(12) Patent Application Publication
(10) Pub. No.: US 2004/0119090 A1
(43) Pub. Date: Jun. 24, 2004

(54) GaAs semiconductor device

(76) Inventors: Hsien-Chin Chiu, Taipei (TW); Shih-Cheng Yang, Taichung (TW); Yi-Jen Chan, Jungli City (TW); Tsung-Jung Yeh, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/327,005

(22) Filed: Dec. 24, 2002

(51) Int. Cl. H01L 31/0328; H01L 31/0336; H01L 31/072; H01L 31/109

(52) U.S. Cl. 257/194

(57) ABSTRACT

A GaAs semiconductor device comprising a FET (field effect transistor), and a low dielectric constant passivation. The passivation protects the surface of the active area of the FET under the FET. The FET is a high electron mobility transistor or a pseudomorphic high electron mobility transistor. The passivation is formed by spin coating and made of a low dielectric constant compound. The low dielectric constant compound is Benzocyclobutene. Advantages are a simple manufacturing process, fewer surface defects, and improved device performance. Therefore, a superior device is provided at a reduced production cost.

### BACKGROUND OF THE INVENTION

1. Field of the Invention

The present invention relates to a semiconductor device, and more particularly, to a GaAs semiconductor device with a low dielectric constant passivation material.

2. Description of the Related Art

GaAs semiconductor devices offer advantages such as high output power, low dc power dissipation, high electron mobility mechanism, better device linearity, and low noise. Particularly, at high frequency (above 1 GHz), the GaAs semiconductor device has better performance characteristics than devices of silicon substrates. Therefore, GaAs semiconductor devices are widely used in the field of wireless communication systems and devices. When the operating temperature of a GaAs semiconductor device is increased to 200° C., the reliability of a GaAs semiconductor device is still not influenced by high frequency. Further, the GaAs semiconductor device has the benefit of operating with low noise at high frequency (20 GHz). Therefore, GaAs compound semiconductor devices are used in cell phones, satellite communications and global position systems.

In order to isolate environmental effects, i.e. human contact, oxygen, water or micro pollution, and to enhance the stability and lifetime of the circuits, the GaAs semiconductor device must have passivation formed on the surface of active areas. Silicon nitride (SiNₓ) is traditionally applied in passivation of semiconductor devices or insulation layers and is used in the passivation of GaAs semiconductor devices to prevent defects and oxygen from damaging the surface of active areas.

In conventional technology, the passivation made of silicon nitride is formed by Plasma Enhanced Chemical Vapor Deposition or Electron Cyclotron Resonance Chemical Vapor Deposition. However, these methods of deposition damage and destroy the surface of active areas. Furthermore, the dielectric constant passivation of silicon nitride is about 6 to 8, causing signal loss at high frequencies.

### SUMMARY OF THE INVENTION

It is an object of the present invention to provide a GaAs semiconductor device having low dielectric constant passivation thus reducing capacitance effects.

It is another object of the present invention to provide spin coating at low treatment temperature for forming the passivation of the GaAs semiconductor device.

It is yet another object of the present invention to provide passivation of an GaAs semiconductor device for reducing defects on the surface of active areas during plasma treatment and to prevent defects forming in plasma deposition.

It is yet another object of the present invention to provide a GaAs semiconductor device formed by spin coating for reducing production costs.

The present invention provides a GaAs semiconductor device comprising a FET and passivation. The passivation on the surface of the FET protects the active area of or under the FET. The FET is a high electron mobility transistor or pseudomorphic high electron mobility transistor. The passivation is formed by spin coating and made of a low dielectric constant compound, for example, Benzocyclobutene.

According to the above objects, the present invention provides a low dielectric passivation on a GaAs semiconductor device which reduces parasitic capacitance effects. Spin coating prior to a low treatment temperature may form the passivation of the GaAs semiconductor device. Using this technique, the passivation of the GaAs semiconductor device reduces or eliminates defects on the surface of active area layers and prevents defects from forming during plasma deposition. Furthermore, the present invention utilizes spin coating during production of the GaAs semiconductor device which reduces the cost of production.

For the purpose of illustrating the invention, there is shown in the drawings several preferred embodiments of the present invention, it being understood, however, that the invention is not limited to the precise arrangement and instrumentality shown.

### BRIEF DESCRIPTION OF THE DRAWINGS

FIG. 1 is a schematic sectional view illustrating the structure for a GaAs semiconductor device according to an embodiment of the present invention;

FIG. 2 is a graph illustrating a comparison of the bi-polar voltage versus gate leakage for a semiconductor device with and without Benzocyclobutene passivation;

FIG. 3 is a graph illustrating a comparison of the GaAs semiconductor source/drain current versus voltage for a semiconductor device with and without Benzocyclobutene passivation;

FIG. 4 is a graph illustrating a comparison of the GaAs semiconductor surface defect characterization for a semiconductor device with and without Benzocyclobutene passivation;

FIG. 5 is a graph illustrating a comparison of the GaAs semiconductor high frequency characterization for a semiconductor device with and without Benzocyclobutene passivation;

FIG. 6 is a graph illustrating a comparison of the GaAs semiconductor gate leakage current versus input power for a semiconductor device with and without Benzocyclobutene passivation; and

FIG. 7 is a graph illustrating a comparison of the GaAs semiconductor output power and power added efficiency versus input power for a semiconductor device with and without Benzocyclobutene passivation.

### DETAILED DESCRIPTION OF PREFERRED EMBODIMENTS

Hereinafter, the preferred embodiments of the present invention are explained in detail with reference to the drawings.

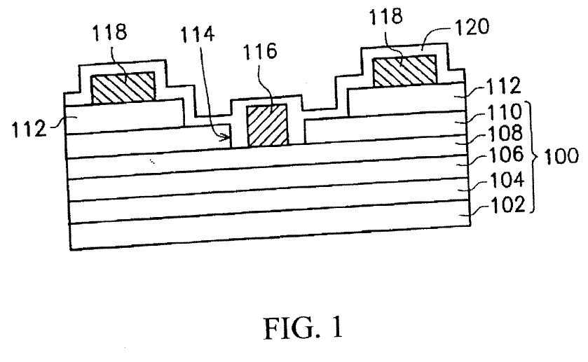

Refer to FIG. 1, which shows a pseudomorphic high electron mobility transistor, PHEMT, for the GaAs semiconductor device. The GaAs semiconductor device includes a stack structure 100, an ohmic contact 112, gate 116 and passivation 120. The stack structure 110 includes a base 102, a buffer layer 104, a channel layer 106, a buried layer 108 and an n+ implement or cap layer 110 stacked in order. The base 100 is comprised of GaAs. The buffer layer is also comprised of GaAs. The channel layer is comprised of GaAs or GaAsIn. Note, if the channel layer is GaAs, the GaAs semiconductor device is HEMT type and if the channel layer is GaAsIn, the GaAs semiconductor device is PHEMT type. The buried layer 108 comprised of AsGaAs, is a Schottky Layer. The n+ implement layer 110 is comprised of GaAs implementing n+.

The stack structures 100 comprises an opening 114, and the buried layer is exposed on the bottom of the opening 114. The gate 116 on the opening 114 connects to an electrode of the buried layer 108. The gate is made of, for example, Ti/Au alloy formed by, for example, electron beam gun Evaporation.

Ohmic contact 112 is located under the n+ implement layer at the two sides of opening 114. The ohmic contact 112 is made of, for example, Au/Ge/Ni alloy and formed by, for example, electron beam gun Evaporation.

As described above, the stack structure 110 comprises, an ohmic contact 112, and gate 116, which is HEMT or PHEMT.

Passivation 120 is over the active area of the device. The passivation is comprised of a material with a low dielectric constant lower than silicon nitride compound, for example, Benzocyclobutene, BCB. The passivation 120 is formed by, for example, spin coating.

Under the ohmic electrodes 112 (source and drain electrodes) can be formed a metallic layer 118 comprised of Ti/Au alloy formed by, for example, vacuum electric vapor deposition. The metallic layer is a contact window for connecting outside circuits.

Hereinafter, an embodiment of the present invention is compared with a semiconductor device without passivation. According to an embodiment of the present invention as illustrated in FIG. 1, the GaAs semiconductor device section structure and a method of producing the same will be described as follows.

First, to define the plane area for isolating the active area: Provide a sample of a stack structure 100 as shown in FIG. 1. Use tricholoethane, acetone and iso-acetone to clean the sample. A photoresist (for example, trade name AZ1400) is overlaid on the sample at a speed of 6500 rpm spinning for 30 sec. Then, soft bake the sample at 70 to 75 degrees C. for 2 minutes. After exposing in UV for 15 seconds, the sample is developed in a developer (for example, trade name AZ351) solution in a ratio of 1:3 for 10 seconds; the plane area will be defined by photoresist. Then, etch the area not protected by photoresist at about 2000 A. The etching solution is prepared by ammonia, H₂O₂ and pure water in a ratio of 3:1:100. Further, the photoresist is removed by dissolving in acetone. The plane area is formed under the sample.

Next, the process for forming the ohmic area 112, referenced in FIG. 1. is described:

A photoresist (for example, trade name AZ400) is overlaid on the sample at 6500 rpm spinning for 30 sec. Then, soft bake the sample at 70 to 75 degrees C. for 2 minutes. Further, hard bake at 100 to 105 degrees C. After exposing in UV for 15 seconds, the sample is developed in a developer (for example, trade name AZ351) solution in a ratio of 1:3 for about 10 seconds, and the ohmic area will be defined by photoresist photography. Then, etch the oxygen layer for 15 seconds in etching solution prepared by ammonia hydroxide solution in a ratio of 1:10. Further, the sample is cleared by pure water and dried by nitrogen gas. Plate the sample at 2200 A with Au/Ge/Ni at a composition of 84/14/2. Then, by lifting-off, the photoresist is dissolved completely from the undefined metal layer in acetone. Then, preheat the sample at 200 degrees C. for 60 seconds and anneal for 120 seconds at 420 degrees C., so that between the metal layer and semiconductor is rendered an ohmic contact.

Next, the process for forming the Schottky electrode 116 is described. A photoresist (for example, trade name AZ1400) is overlaid on the sample at 6500 rpm, spinning for 30 sec. Then, hard bake the sample at 100 to 105 degrees C. for 2 minutes. After exposing in deep UV for 40 minutes, the photography layer on the sample is defined by photoresist. Further, by wet etching on the sample, remove the n+ implement layers not protected by photoresist and form opening 114. The etching solution is prepared by NH₄OH ,H₂O₂ and water in a ratio of 3:1:750. Then, etch the oxygen layer for 15 seconds in etching solution prepared by NH₄OH and water in a ratio of 1:10. Further, the sample is cleared by pure water and dried by nitrogen gas. After the above process, plate the sample with 300/2000 A Ti/Au by high vacuum evaporation and by lifting-off, the photoresist is dissolved completely from the undefined mental layer in acetone. Then, the gate is formed. Next the process for producing the metal line area 118 is described. A photoresist (for example, trade name AZ1400) is overlaid on the sample at 6500 rpm spinning for 30 sec. Then, hard bake the sample at 100 to 105 degrees C. for 2 minutes. After exposing in UV for 14.5 seconds, the sample is developed in developer (for example, trade name AZ351) solution in at a ratio of 1:5 for 10 seconds; the metal line area on the sample is defined by photoresist. Etch the oxygen layer for 15 seconds in etching solution prepared by NH₄OH and water in a ratio of 1:10. Then, the sample is cleared by pure water and dried by nitrogen gas. After the above process, the sample is plated with 500 A Ti by high vacuum evaporation and 2000 A Au, respectively. Then, by lifting-off, the photoresist is dissolved completely from the undefined mental layer in acetone.

Describe above is the process of producing the semiconductor device (from defining the plane to the metallic line area) which is HEMT or PHEMT without passivation.

Finally, forming the passivation 120:

First put the sample into plasma etching equipment and utilize oxygen plasma to etch the sample surface for about 30 seconds. Then use ammonia solution (mixing ratio NH₄OH: H₂O=1:10) to remove the remaining particles induced by plasma etching and the oxide layer. Second, use nitrogen to dry out the sample surface and then utilize spin coating to spread BCB solution (8000 rpm, 90 sec) on the surface in order to get better uniformity. Third, hard bake for 2 minutes under 75˜80 degrees C. temperature and then expose for 14.5 seconds in UV light. Develop for 60 minutes using developer (for example, trade name DS3000) to define a passivation area covering the device active area. Finally, put the sample into a hot baker and bake for 30 minutes at 200 degrees C. Thus, an embodiment of present invention, a semiconductor device with BCB passivation, is formed.

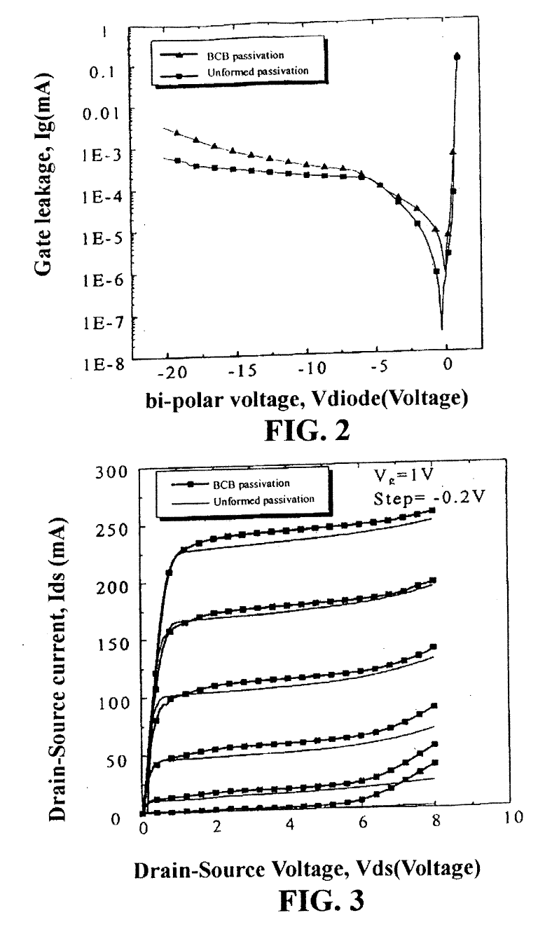

Refer to FIG. 2, which is a graph illustrating a comparison of the bi-polar voltage versus gate leakage for the semiconductor device with and without Benzocyclobutene passivation. As shown in FIG. 2, the breakdown voltage and threshold voltage of a semiconductor device with BCB passivation (square mark) is −12 volts and 0.95 volts and without BCB passivation (triangle mark) is −10 volts and 0.9 volts. Obviously, the leakage curren of the device with passivation is eliminated.

Refer to FIG. 3, which is a graph illustrating a comparison of the GaAs semiconductor source/drain current versus voltage for the semiconductor device with and without Benzocyclobutene passivation. In accordance, the present invention reduced the leakage current of the device, while at the same time the high drain bias character of the device with passivation is increased.

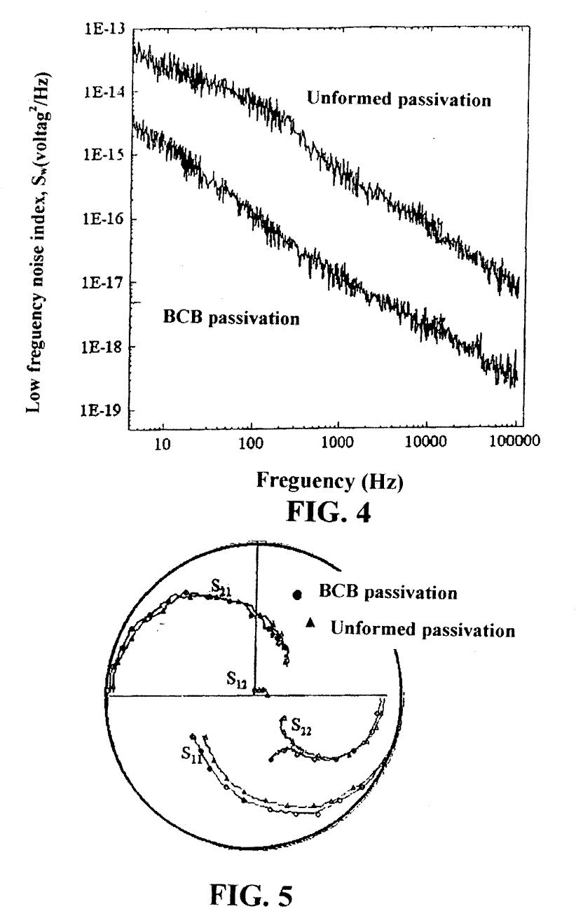

Refer to FIG. 4 which is a graph illustrating a comparison of the GaAs semiconductor surface defect characterization for a semiconductor device with and without Benzocyclobutene passivation. After a low frequency noise testing process, the device with BCB passivation compared to a device without passivation, the surface defects of the device with passivation is lower than without passivation. Thus, the device with BCB passivation has superior high frequency characteristics.

Refer to FIG. 5, which is a graph illustrating a comparison of the GaAs semiconductor high frequency characterization for a semiconductor device with and without Benzocyclobutene passivation. Testing with high frequency network analyzer equipment, the S-parameter of the semiconductor device with BCB passivation compared to a device without BCB passivation is different. The gain and power for the device after coating BCB passivation only exhibits 5% performance reduction as compared with the device without passivation layer. From those results, the device can maintain the high frequency characterization after coating BCB passivation layer.

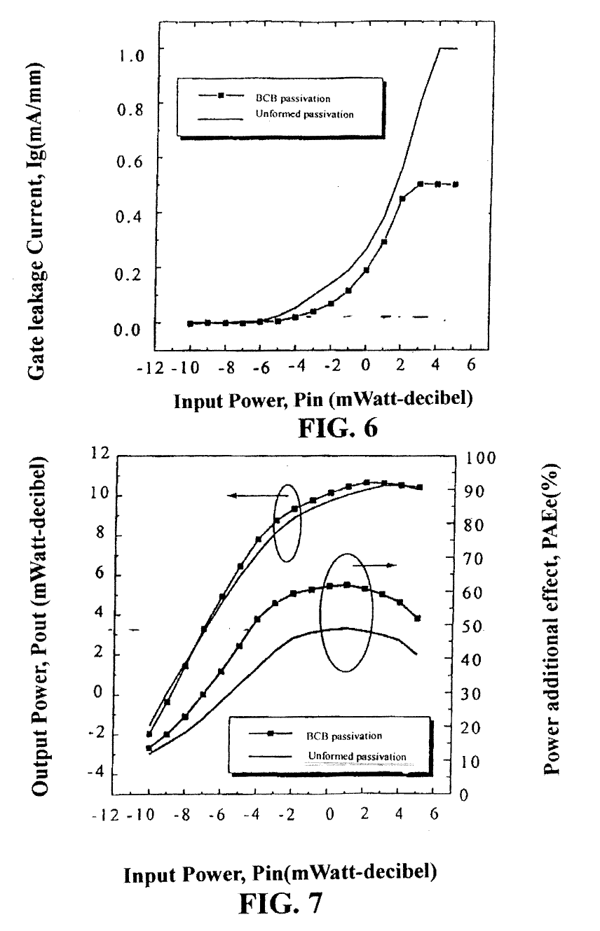

Refer to FIG. 6, which is a graph illustrating a comparison of the GaAs semiconductor input power versus gate leakage for a semiconductor device with and without Benzocyclobutene passivation. During high output power applications, the gate leakage current of the semiconductor device without BCB passivation is higher than that of the semiconductor device with BCB passivation. As described above, the semiconductor device with BCB passivation has improved gate leakage current at high power.

Next, refer to FIG. 7, which is a graph illustrating a comparison of the GaAs semiconductor output power and power added efficiency versus input power for a semiconductor device with and without Benzocyclobutene passivation. The semiconductor device with BCB passivation improves the gate leakage current at high power. As a result, at high power, the semiconductor device with BCB passivation has a lower power decay, a higher output power and power added efficiency.

As seen in the above description, an embodiment of the present invention applies a low dielectric constant material (lower than the dielectric constant of silicon nitride) to form the passivation of the GaAs semiconductor device. According to the GaAs semiconductor device with low dielectric constant passivation, the GaAs semiconductor device has fewer parasitic capacitance and enhanced electrical characterization, such as gate leakage current and breakdown voltage.

Also, in the present invention, the passivation of a GaAs semiconductor device is formed by spin coating, and the treatment temperature is lower.

Further, in the present invention, since the passivation of the GaAs semiconductor device uses a low dielectric constant material and is formed by spin coating, resulting in fewer defects are formed on the surface of active areas than when formed by plasma deposition.

Additionally, the GaAs semiconductor device formed by spin coating has reduced production cost.

While preferred embodiments of the invention have been disclosed, various modes of carrying out the principles disclosed herein are contemplated as being within the scope of the following claims. Therefore, it is understood that the scope of the invention is not to be limited except as otherwise set forth in the claims.

What is claimed is:

1. A GaAs semiconductor device comprising:
a field effect transistor having at least one GaAs compound layer and a plane; and
a spin coating passivation located under the plane of the field effect transistor.

2. The GaAs semiconductor device according to claim 1, wherein the spin coating passivation comprises Benzocyclobutene.

3. The GaAs semiconductor device according to claim 2, wherein the spin coating passivation has a dielectric constant of 2.7 or below.

4. The GaAs semiconductor device according to claim 1, wherein the field effect transistor comprises a pseudomorphic high electron mobility transistor (PHEMT).

5. A GaAs semiconductor device comprising:
a field effect transistor having at least one GaAs compound layer and a plane; and
a protection layer located under the plane of the field effect transistor and having a lower dielectric constant than a dielectric constant of silica nitride.

6. The GaAs semiconductor device according to claim 5, wherein the protection layer comprises Benzocyclobutene.

7. The GaAs semiconductor device according to claim 6, wherein the protection layer has a dielectric constant of 2.7 or below.

8. The GaAs semiconductor device according to claim 5, wherein the protection layer is formed by spin coating.

9. The GaAs semiconductor device according to claim 5, wherein the field effect transistor comprises a pseudomorphic high electron mobility transistor (PHEMT).
